(19) United States
(12) Patent Application Publication
(10) Pub. No.: US 2013/0122619 A1
(43) Pub. Date: May 16, 2013

(54) OPTICAL DEVICE WAFER PROCESSING METHOD

(71) Applicant: Disco Corporation, Tokyo (JP)

(72) Inventor: Chikara AIKAWA, Tokyo (JP)

(73) Assignee: DISCO CORPORATION, Tokyo (JP)

(21) Appl. No.: 13/666,417

(22) Filed: Nov. 1, 2012

(30) Foreign Application Priority Data
Nov. 11, 2011 (JP) 2011-247771

(51) Int. Cl. H01L 33/60

(52) U.S. Cl. 438/29; 438/33; 257/E33.06

(57) ABSTRACT

An optical device wafer is divided into individual optical devices along streets. A modified layer is formed by applying a laser beam to a sapphire substrate constituting the optical device wafer along the streets from the back side of the sapphire substrate such that the focal point of the laser beam is set inside the sapphire substrate, thereby forming a modified layer inside the sapphire substrate along each street. A reflective film is formed on the back side of the sapphire substrate and the reflective film is cut by applying a laser beam along the streets from the back side of the sapphire substrate. The wafer is divided by applying an external force to the optical device wafer to thereby break the optical device wafer along each street where the modified layer is formed, so that the optical device wafer is divided into the individual optical devices.

### BACKGROUND OF THE INVENTION

1. Field of the Invention

The present invention relates to an optical device wafer processing method for dividing an optical device wafer into individual optical devices along a plurality of crossing streets formed on the front side of the optical device wafer, the optical device wafer being composed of a sapphire substrate and an optical device layer formed on the front side of the sapphire substrate, the individual optical devices being respectively formed in a plurality of regions partitioned by the streets.

2. Description of the Related Art

In an optical device fabrication process, an optical device layer of a gallium nitride compound semiconductor is formed on the front side of a substantially disk-shaped sapphire substrate, and this optical device layer is partitioned by a plurality of crossing streets into a plurality of regions where optical devices such as light emitting diodes and laser diodes are respectively formed, thus constituting an optical device wafer. The optical device wafer is cut along the streets to thereby divide the regions where the optical devices are formed from each other, thus obtaining the individual optical devices.

Cutting of the optical device wafer along the streets as described above is usually performed by using a cutting apparatus called a dicing saw. This cutting apparatus includes a chuck table for holding a workpiece, cutting means for cutting the workpiece held on the chuck table, and feeding means for relatively moving the chuck table and the cutting means. The cutting means includes a rotating spindle, a cutting blade mounted on the rotating spindle, and a driving mechanism for rotationally driving the rotating spindle. The cutting blade is composed of a disk-shaped base and an annular cutting edge mounted on a side surface of the base along the outer circumference thereof. The cutting edge is formed by fixing diamond abrasive grains having a grain size of about 3 μm to the base by electroforming so that the thickness of the cutting edge becomes about 20 μm, for example.

However, the sapphire substrate constituting the optical device wafer has high Mohs hardness, so that cutting of the sapphire substrate by the cutting blade is not always easy. Further, the cutting edge of the cutting blade has a thickness of about 20 μm, so that each street partitioning the adjacent devices must have a width of about 50 μm. Accordingly, the ratio of the area of the streets to the area of the devices is large, causing a reduction in productivity.

As a method of dividing an optical device wafer along the streets, a laser processing method using a pulsed laser beam having an absorption wavelength to the wafer has been proposed to solve the above problem. In this laser processing method, the pulsed laser beam is applied to the wafer along the streets to thereby form a laser processed groove on the wafer along each street as a break start point. Thereafter, an external force is applied to the wafer along each street where the laser processed groove is formed as the break start point, thereby breaking the wafer along each street (see Japanese Patent Laid-open No. Hei 10-305420, for example).

However, in the case that a laser beam is applied to a sapphire substrate constituting an optical device wafer along the streets formed on the front side of the sapphire substrate to thereby form a laser processed groove along each street, there is a problem such that a fused substance called debris may be produced by ablation of the sapphire substrate and deposited to the outer edge of each optical device such as a light emitting diode, causing a reduction in luminance of each optical device, so that the quality of each optical device is reduced. To solve this problem, it is necessary to perform an additional step of removing the debris by etching prior to dividing the optical device wafer into the individual optical devices, causing a reduction in productivity.

As a method for solving this problem, there is disclosed in Japanese Patent No. 3408805 a laser processing method including the steps of applying a laser beam having a transmission wavelength to a sapphire substrate along the streets from the back side of the sapphire substrate where a light emitting layer (epitaxial layer) as an optical device layer is not formed in the condition where the focal point of the laser beam is set inside the sapphire substrate, thereby forming a modified layer inside the sapphire substrate along each street, and next dividing the sapphire substrate along each street where the modified layer is formed.

### SUMMARY OF THE INVENTION

In the case of an optical device wafer composed of a sapphire substrate and an optical device layer formed on the front side of the sapphire substrate, there has been proposed a technique of forming a reflective film of gold, aluminum, etc. on the back side of the sapphire substrate in order to reflect light emitted from the optical device layer and thereby improve a light output efficiency.

However, in processing an optical device wafer having a reflective film of gold, aluminum, etc. formed on the back side of a sapphire substrate, there is a problem such that the reflective film may hinder the laser beam applied from the back side of the sapphire substrate.

It is therefore an object of the present invention to provide an optical device wafer processing method which can form a modified layer inside a sapphire substrate along each street even in the case of forming a reflective film on the back side of the sapphire substrate, by applying a laser beam having a transmission wavelength to the sapphire substrate along each street from the back side of the sapphire substrate in the condition where the focal point of the laser beam is set inside the sapphire substrate.

It is another object of the present invention to provide an optical device wafer processing method which can cut the reflective film formed on the back side of the sapphire substrate along each street.

In accordance with an aspect of the present invention, there is provided an optical device wafer processing method for dividing an optical device wafer into individual optical devices along a plurality of crossing streets formed on the front side of the optical device wafer, the optical device wafer being composed of a sapphire substrate and an optical device layer formed on the front side of the sapphire substrate, the individual optical devices being respectively formed in a plurality of regions partitioned by the streets, the optical device wafer processing method including a modified layer forming step of applying a laser beam having a transmission wavelength to the sapphire substrate along the streets from the back side of the sapphire substrate in the condition where the focal point of the laser beam is set inside the sapphire substrate, thereby forming a modified layer inside the sapphire substrate along each street; a reflective film forming step of forming a reflective film on the back side of the sapphire substrate after performing the modified layer forming step; a reflective film cutting step of applying a laser beam having an absorption wavelength to the reflective film along the streets from the back side of the sapphire substrate after performing the reflective film forming step, thereby cutting the reflective film along each street; and a wafer dividing step of applying an external force to the optical device wafer after performing the reflective film cutting step, thereby breaking the optical device wafer along each street where the modified layer is formed, so that the optical device wafer is divided into the individual optical devices.

Preferably, the reflective film includes a metal film having a thickness of 0.5 to 2 μm. Alternatively, the reflective film includes an oxide film having a thickness of 0.5 to 2 μm.

As described above, the optical device wafer processing method according to the present invention includes the modified layer forming step of applying a laser beam having a transmission wavelength to the sapphire substrate along the streets from the back side of the sapphire substrate in the condition where the focal point of the laser beam is set inside the sapphire substrate, thereby forming a modified layer inside the sapphire substrate along each street, the reflective film forming step of forming a reflective film on the back side of the sapphire substrate after performing the modified layer forming step, and the reflective film cutting step of applying a laser beam having an absorption wavelength to the reflective film along the streets from the back side of the sapphire substrate after performing the reflective film forming step, thereby cutting the reflective film along each street. Accordingly, a modified layer can be formed inside the sapphire substrate along each street even in the case of forming a reflective film on the back side of the sapphire substrate. Further, the reflective film formed on the back side of the sapphire substrate can be cut along each street.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of an optical device wafer to be divided into individual optical devices by the optical device wafer processing method according to the present invention;

FIG. 2 is a perspective view showing a condition that a protective tape is attached to the front side of the optical device wafer shown in FIG. 1;

FIG. 3 is a perspective view showing an essential part of a laser processing apparatus for performing a modified layer forming step in the optical device wafer processing method according to the present invention;

FIGS. 4A and 4B are sectional side views for illustrating the modified layer forming step;

FIG. 5 is a schematic sectional view of a sputtering apparatus for performing a reflective film forming step in the optical device wafer processing method according to the present invention;

FIG. 6 is a perspective view of the optical device wafer processed by the reflective film forming step shown in FIG. 5;

FIG. 7 is a perspective view showing a laser processing apparatus for performing a reflective film cutting step in the optical device wafer processing method according to the present invention;

FIGS. 8A and 8B are sectional side views for illustrating the reflective film cutting step shown in FIG. 7;

FIG. 8C is a perspective view of the optical device wafer processed by the reflective film cutting step;

FIG. 9 is a perspective view showing a wafer supporting step and a protective tape peeling step in the optical device wafer processing method according to the present invention;

FIG. 10 is a perspective view of a wafer dividing apparatus for performing a wafer dividing step in the optical device wafer processing method according to the present invention;

FIGS. 11A and 11B are sectional side views for illustrating the wafer dividing step using the wafer dividing apparatus shown in FIG. 10; and

FIG. 12 is a sectional side view for illustrating a pickup step in the optical device wafer processing method according to the present invention.

### DETAILED DESCRIPTION OF THE PREFERRED EMBODIMENTS

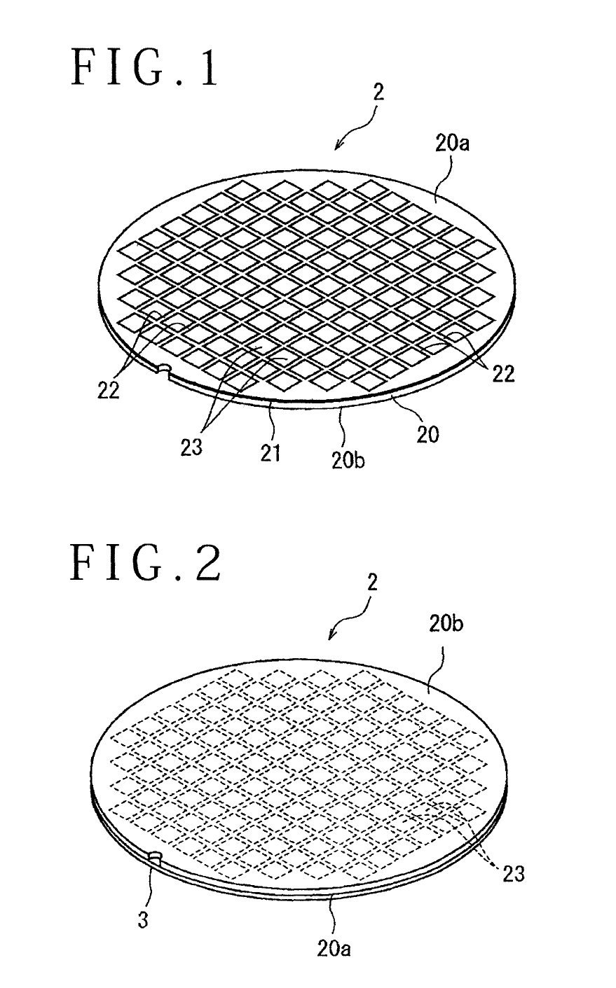

A preferred embodiment of the optical device wafer processing method according to the present invention will now be described in detail with reference to the attached drawings. FIG. 1 is a perspective view of an optical device wafer 2 to be divided into individual optical devices by the optical device wafer processing method according to the present invention. The optical device wafer 2 shown in FIG. 1 is composed of a sapphire substrate 20 having a front side 20a and a back side 20b and an optical device layer (epitaxial layer) 21 formed on the front side 20a of the sapphire substrate 20. For example, the sapphire substrate 20 has a diameter of 150 mm and a thickness of 120 μm. The optical device layer 21 is composed of an n-type nitride semiconductor layer and a p-type nitride semiconductor layer. For example, the optical device layer 21 has a thickness of 5 μm. The optical device layer 21 is partitioned by a plurality of crossing streets 22 to define a plurality of rectangular regions where a plurality of optical devices 23 such as light emitting diodes and laser diodes are respectively formed. As shown in FIG. 2, a protective tape 3 for protecting the optical devices 23 is attached to the front side 20a of the sapphire substrate 20 constituting the optical device wafer 2 (protective tape attaching step).

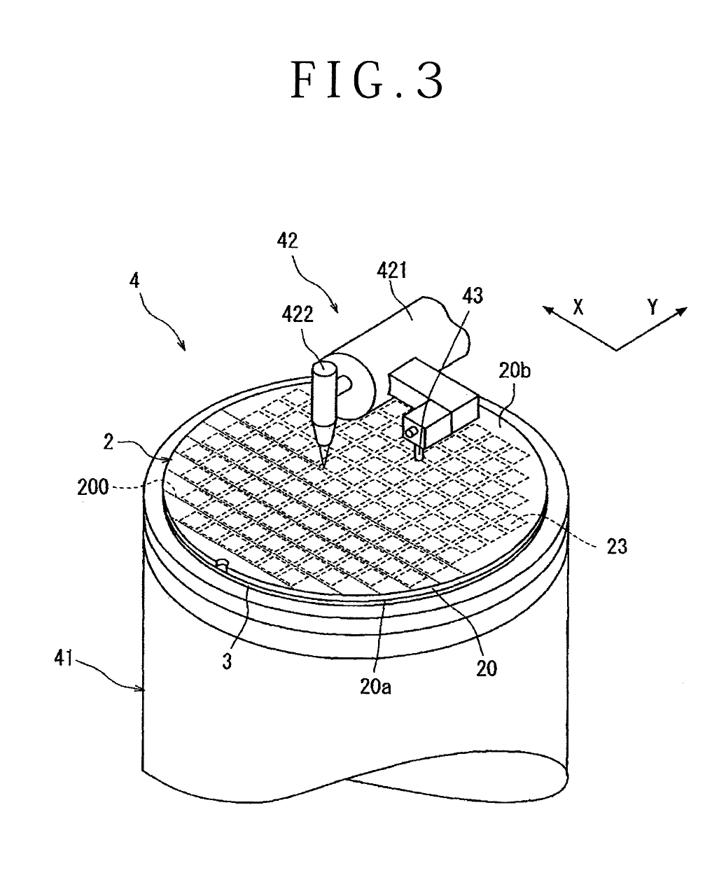

After performing the protective tape attaching step, a modified layer forming step is performed in such a manner that a laser beam having a transmission wavelength to the sapphire substrate 20 is applied along the streets 22 from the back side 20b of the sapphire substrate 20 in the condition where the focal point of the laser beam is set inside the sapphire substrate 20, thereby forming a modified layer inside the sapphire substrate 20 along each street 22. This modified layer forming step is performed by using a laser processing apparatus 4 shown in FIG. 3. As shown in FIG. 3, the laser processing apparatus 4 includes a chuck table 41 for holding a workpiece, laser beam applying means 42 for applying a laser beam to the workpiece held on the chuck table 41, and imaging means 43 for imaging the workpiece held on the chuck table 41. The chuck table 41 is so configured as to hold the workpiece under suction by using suction means (not shown). The chuck table 41 is movable both in the direction shown by an arrow X in FIG. 3 by feeding means (not shown) and in the direction shown by an arrow Y in FIG. 3 by indexing means (not shown).

The laser beam applying means 42 includes a cylindrical casing 421 extending in a substantially horizontal direction and focusing means 422 mounted on the front end of the casing 421 for applying a pulsed laser beam. The imaging means 43 is mounted on a front end portion of the casing 421 and includes optical means such as a microscope and a CCD camera. An image signal output from the imaging means 43 is transmitted to control means (not shown).

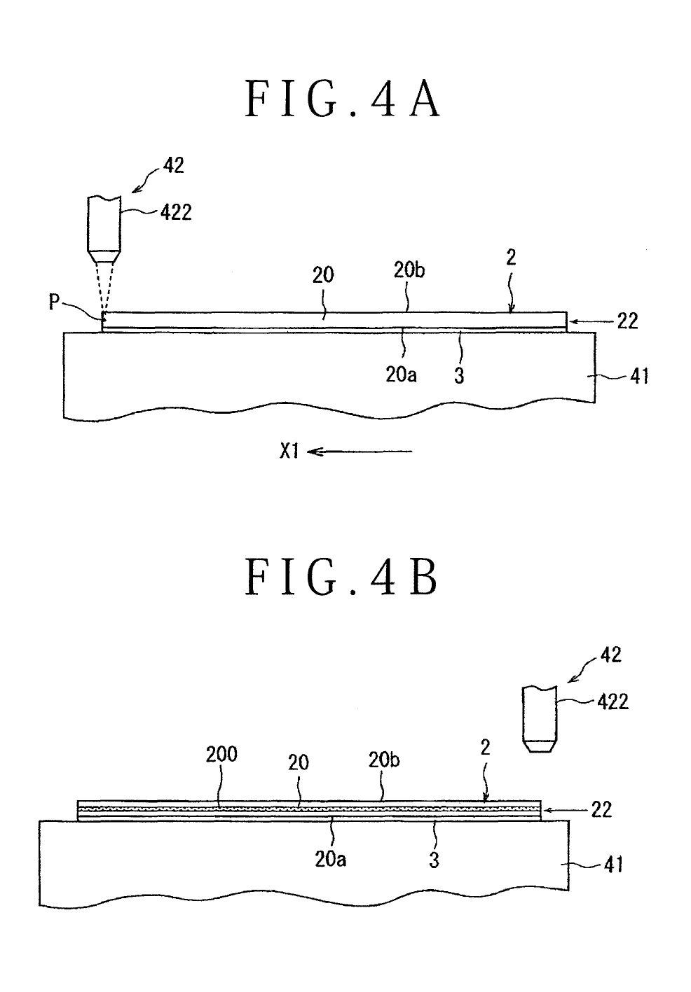

The modified layer forming step using the laser processing apparatus 4 will now be described with reference to FIGS. 3, 4A, and 4B. First, the optical device wafer 2 is placed on the chuck table 41 of the laser processing apparatus 4 in the condition where the protective tape 3 attached to the front side 20a of the sapphire substrate 20 constituting the optical device wafer 2 is in contact with the chuck table 41 as shown in FIG. 3. Thereafter, the suction means (not shown) is operated to hold the optical device wafer 2 on the chuck table 41 under suction. Accordingly, the back side 20b of the sapphire substrate 20 constituting the optical device wafer 2 held on the chuck table 41 is oriented upward. Thereafter, the chuck table 41 thus holding the optical device wafer 2 is moved to a position directly below the imaging means 43 by the feeding means (not shown).

In the condition where the chuck table 41 is positioned directly below the imaging means 43, an alignment operation is performed by the imaging means 43 and the control means (not shown) to detect a subject area of the optical device wafer 2 to be laser-processed along each street 22 formed on the front side 20a of the sapphire substrate 20 of the wafer 2. More specifically, the imaging means 43 and the control means perform image processing such as pattern matching for making the alignment of the streets 22 extending in a first direction on the sapphire substrate 20 and the focusing means 422 of the laser beam applying means 42 for applying the laser beam to the sapphire substrate 20 along the streets 22, thus performing the alignment of a laser beam applying position. Similarly, the alignment of a laser beam applying position is performed for the other streets 22 extending in a second direction perpendicular to the first direction on the sapphire substrate 20.

After performing the alignment operation mentioned above, the chuck table 41 is moved to a laser beam applying area where the focusing means 422 of the laser beam applying means 42 is located as shown in FIG. 4A, thereby positioning one end (left end as viewed in FIG. 4A) of a predetermined one of the streets 22 extending in the first direction directly below the focusing means 422 of the laser beam applying means 42. Further, the focal point P of the pulsed laser beam to be applied from the focusing means 422 is set at a depth of 60 μm, for example, from the back side 20b (upper surface as viewed in FIG. 4A) of the sapphire substrate 20 constituting the optical device wafer 2. In this condition, a pulsed laser beam having a transmission wavelength to the sapphire substrate 20 is applied from the focusing means 422 to the sapphire substrate 20, and the chuck table 41 is moved in the direction shown by an arrow X1 in FIG. 4A at a predetermined feed speed. Accordingly, the pulsed laser beam is scanned along the predetermined street 22.

When the other end (right end as viewed in FIG. 4B) of the predetermined street 22 reaches the position directly below the focusing means 422 of the laser beam applying means 42 as shown in FIG. 4B, the application of the pulsed laser beam is stopped and the movement of the chuck table 41 is also stopped. As a result, a modified layer 200 is formed inside the sapphire substrate 20 of the optical device wafer 2 along the predetermined street 22 at an intermediate depth from the back side 20b of the sapphire substrate 20 (at an intermediate position along the thickness of the sapphire substrate 20) as shown in FIG. 4B. This modified layer 200 is formed as a melted and rehardened layer.

For example, the modified layer forming step mentioned above is performed under the following processing conditions.

Light source: LD pumped Q-switched Nd: YVO4 pulsed laser

Wavelength: 1064 nm

Repetition frequency: 100 kHz

Average power: 0.1 to 0.4 W

Focused spot diameter: 1 μm

Work feed speed: 300 to 800 mm/s

Under the above processing conditions, the thickness of the modified layer 200 formed inside the sapphire substrate 20 is about 30 μm. After performing the modified layer forming step along all of the streets 22 extending in the first direction on the sapphire substrate 20 of the optical device wafer 2, the chuck table 41 is rotated 90° to similarly perform the modified layer forming step along all of the other streets 22 extending in the second direction perpendicular to the first direction on the sapphire substrate 20 of the optical device wafer 2.

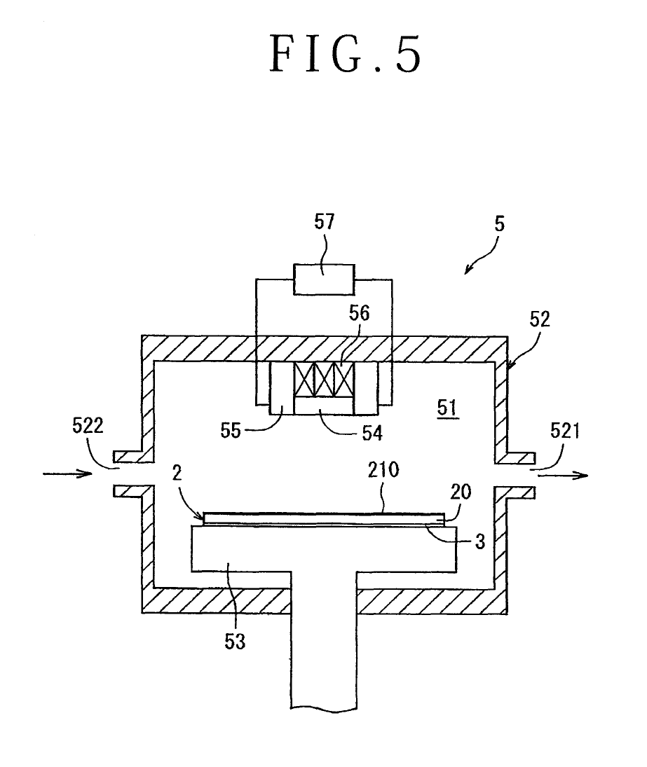

After performing the modified layer forming step along all of the streets 22 extending in the first and second directions as mentioned above, a reflective film forming step is performed in such a manner that a reflective film is formed on the back side 20b of the sapphire substrate 20 in which the modified layers 200 have been formed. This reflective film forming step is performed by using a sputtering apparatus 5 shown in FIG. 5. As shown in FIG. 5, the sputtering apparatus 5 includes a housing 52 defining a sputter chamber 51, an electrostatic chuck type holding table 53 as an anode provided in the sputter chamber 51 for holding the workpiece, a cathode 55 provided in the sputter chamber 51 so as to be opposed to the holding table 53 for mounting a target 54 of metal (e.g., gold or aluminum) or oxide (e.g., SiO₂, TiO₂, or ZnO) to be deposited to the workpiece, exciting means 56 for exciting the target 54, and a radio-frequency power supply 57 for applying a radio-frequency voltage to the cathode 55. The housing 52 is formed with an evacuation hole 521 for making the communication between the sputter chamber 51 and evacuating means (not shown) and a gas inlet 522 for making the communication between the sputter chamber 51 and sputter gas supplying means (not shown).

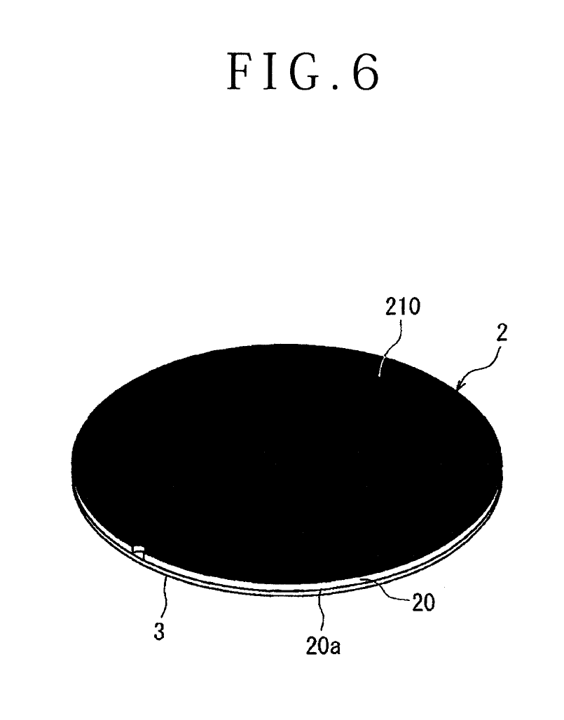

The reflective film forming step using the sputtering apparatus 5 is performed in the following manner. The optical device wafer 2 is electrostatically held on the holding table 53 in the condition where the protective tape 3 attached to the front side 20a of the sapphire substrate 20 constituting the optical device wafer 2 is in contact with the holding table 53. Accordingly, the back side 20b of the sapphire substrate 20 of the optical device wafer 2 held on the holding table 53 is oriented upward so as to be opposed to the target 54. Thereafter, the exciting means 56 is operated to excite the target 54, and a radio-frequency voltage having a frequency of 40 kHz, for example, is applied from the radio-frequency power supply 57 to the cathode 55. The evacuating means not shown is operated to evacuate the sputter chamber 51 to about 10⁻² to 10⁻⁴ Pa, and the sputter gas supplying means is operated to introduce an argon gas into the sputter chamber 51 to generate a plasma. Accordingly, argon ions in the plasma collide with the target 54 of metal (e.g., gold or aluminum) or oxide (e.g., SiO₂, TiO₂, or ZnO) mounted on the cathode 55 to thereby eject metal particles or oxide particles from the surface of the target 54. The metal particles or the oxide particles thus ejected from the target 54 are deposited to the back side 20b of the sapphire substrate 20 constituting the optical device wafer 2. As a result, a reflective film 210 of metal or oxide is formed on the back side 20b of the sapphire substrate 20 as shown in FIG. 6. The thickness of the reflective film 210 is set to 0.5 to 2 μm.

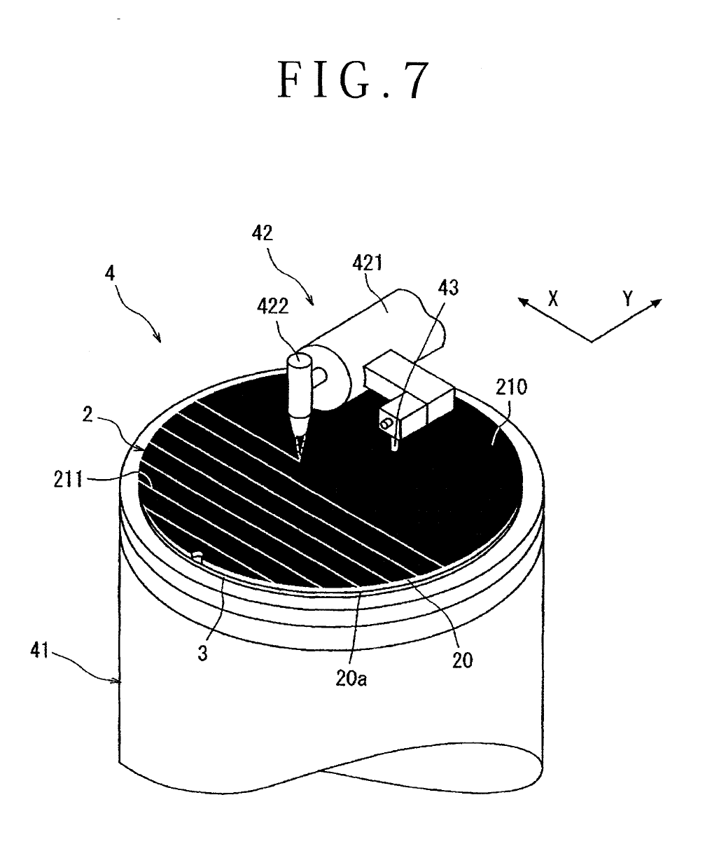

After performing the reflective film forming step, a reflective film cutting step is performed in such a manner that a laser beam having an absorption wavelength to the reflective film 210 is applied along the streets 22 from the back side 20b of the sapphire substrate 20, thereby cutting the reflective film 210 along each street 22. In the case that the reflective film 210 is a transparent film such as an oxide film of SiO₂, for example, the reflective film cutting step may be performed by using a laser processing apparatus similar to the laser processing apparatus 4 shown in FIG. 3. In this case, the reflective film cutting step using the laser processing apparatus 4 is performed in the following manner as shown in FIG. 7. First, the optical device wafer 2 with the reflective film 210 formed on the back side 20b of the sapphire substrate 20 is placed on the chuck table 41 of the laser processing apparatus 4 in the condition where the protective tape 3 attached to the front side 20a of the sapphire substrate 20 constituting the optical device wafer 2 is in contact with the chuck table 41 as shown in FIG. 7. Thereafter, the suction means (not shown) is operated to hold the optical device wafer 2 on the chuck table 41 under suction. Accordingly, the reflective film 210 formed on the back side 20b of the sapphire substrate 20 constituting the optical device wafer 2 held on the chuck table 41 is oriented upward. Thereafter, the chuck table 41 thus holding the optical device wafer 2 is moved to a position directly below the imaging means 43 by the feeding means (not shown).

In the condition where the chuck table 41 is positioned directly below the imaging means 43, an alignment operation is performed by the imaging means 43 and the control means (not shown) to detect a subject area of the optical device wafer 2 to be laser-processed along each street 22 formed on the front side 20a of the sapphire substrate 20 of the wafer 2. More specifically, the imaging means 43 and the control means perform image processing such as pattern matching for making the alignment of the streets 22 extending in the first direction on the sapphire substrate 20 and the focusing means 422 of the laser beam applying means 42 for applying the laser beam to the sapphire substrate 20 along the streets 22, thus performing the alignment of a laser beam applying position. Similarly, the alignment of a laser beam applying position is performed for the other streets 22 extending in the second direction perpendicular to the first direction on the sapphire substrate 20. In the case that the reflective film 210 is formed by a metal film of gold, for example, a holding portion of the chuck table 41 for holding the workpiece may be formed by a transparent member. In this case, the streets 22 formed on the front side 20a of the sapphire substrate 20 constituting the optical device wafer 2 held on the holding portion of the chuck table 41 are imaged from the lower side of the holding portion to perform the above described alignment.

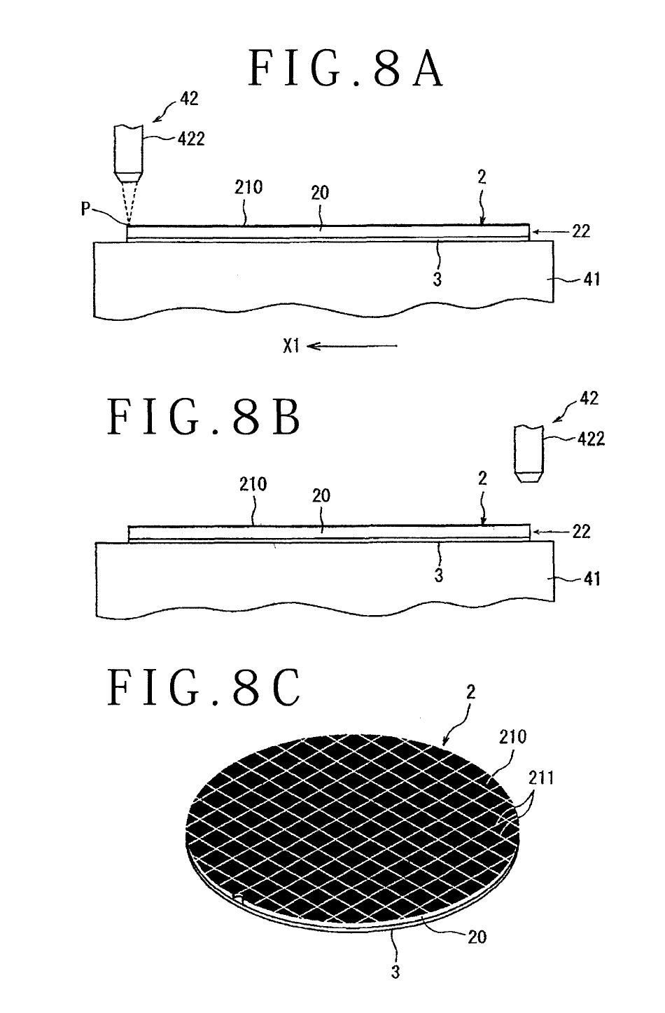

After performing the alignment operation mentioned above, the chuck table 41 is moved to a laser beam applying area where the focusing means 422 of the laser beam applying means 42 is located as shown in FIG. 8A, thereby positioning one end (left end as viewed in FIG. 8A) of a predetermined one of the streets 22 extending in the first direction directly below the focusing means 422 of the laser beam applying means 42. Further, the focal point P of the pulsed laser beam to be applied from the focusing means 422 is set on the upper surface of the reflective film 210 formed on the back side 20b of the sapphire substrate 20 constituting the optical device wafer 2. In this condition, a pulsed laser beam having an absorption wavelength to the reflective film 210 formed on the back side 20b of the sapphire substrate 20 is applied from the focusing means 422 to the reflective film 210, and the chuck table 41 is moved in the direction shown by an arrow X1 in FIG. 8A at a predetermined feed speed. Accordingly, the pulsed laser beam is scanned along the predetermined street 22.

When the other end (right end as viewed in FIG. 8B) of the predetermined street 22 reaches the position directly below the focusing means 422 of the laser beam applying means 42 as shown in FIG. 8B, the application of the pulsed laser beam is stopped and the movement of the chuck table 41 is also stopped. As a result, the reflective film 210 formed on the back side 20b of the sapphire substrate 20 is cut along the predetermined street 22.

For example, the reflective film cutting step mentioned above is performed under the following processing conditions.

Light source: LD pumped Q-switched Nd: YVO4 pulsed laser

Wavelength: 355 nm

Repetition frequency: 100 kHz

Average power: 0.5 to 1.0 W

Focused spot diameter: 1 μm

Work feed speed: 200 mm/s

Under the above processing conditions, the reflective film 210 formed on the back side 20b of the sapphire substrate 20 is cut, but the sapphire substrate 20 is not ablated. After performing the reflective film cutting step along all of the streets 22 extending in the first direction on the sapphire substrate 20 of the optical device wafer 2, the chuck table 41 is rotated 90° to similarly perform the reflective film cutting step along all of the other streets 22 extending in the second direction perpendicular to the first direction on the sapphire substrate 20 of the optical device wafer 2. As a result, a plurality of cut grooves 211 are formed in the reflective film 210 respectively along all of the streets 22 extending in the first and second directions as shown in FIG. 8C.

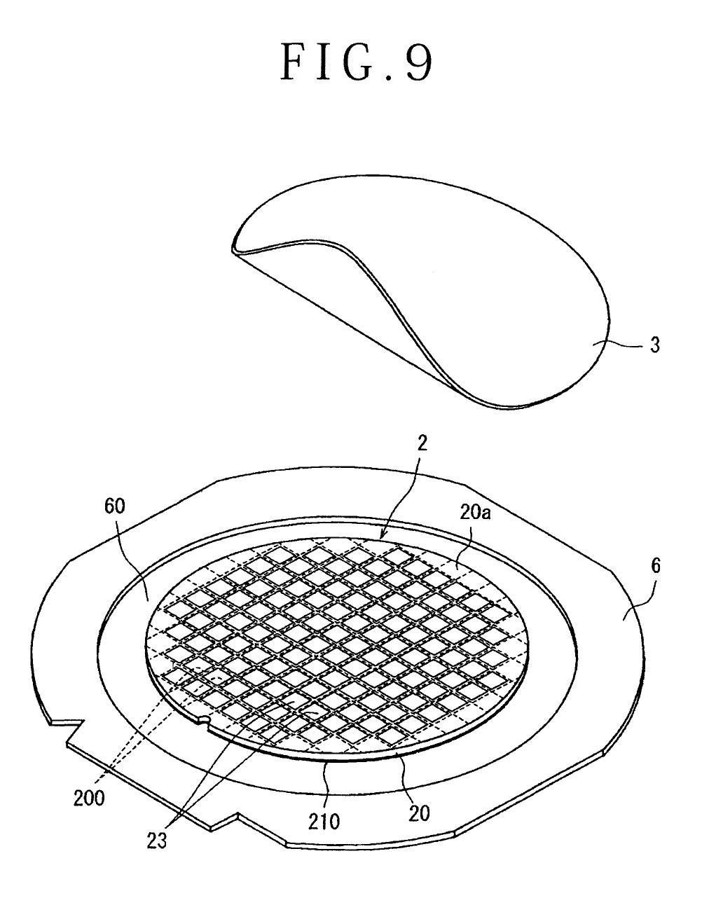

After performing the reflective film cutting step, a wafer supporting step is performed in such a manner that the back side of the optical device wafer 2 with the reflective film 210 formed on the back side 20b of the sapphire substrate 20 is attached to an adhesive tape supported to an annular frame. More specifically, as shown in FIG. 9, an adhesive tape 60 is preliminarily supported at its outer circumferential portion to an annular frame 6 in such a manner as to cover the opening of the annular frame 6. The reflective film 210 formed on the back side 20b of the sapphire substrate 20 constituting the optical device wafer 2 is attached to the adhesive tape 60 in the condition where the front side 20a of the sapphire substrate 20 is oriented upward. Thereafter, the protective tape 3 is peeled off from the front side 20a of the sapphire substrate 20 (protective tape peeling step).

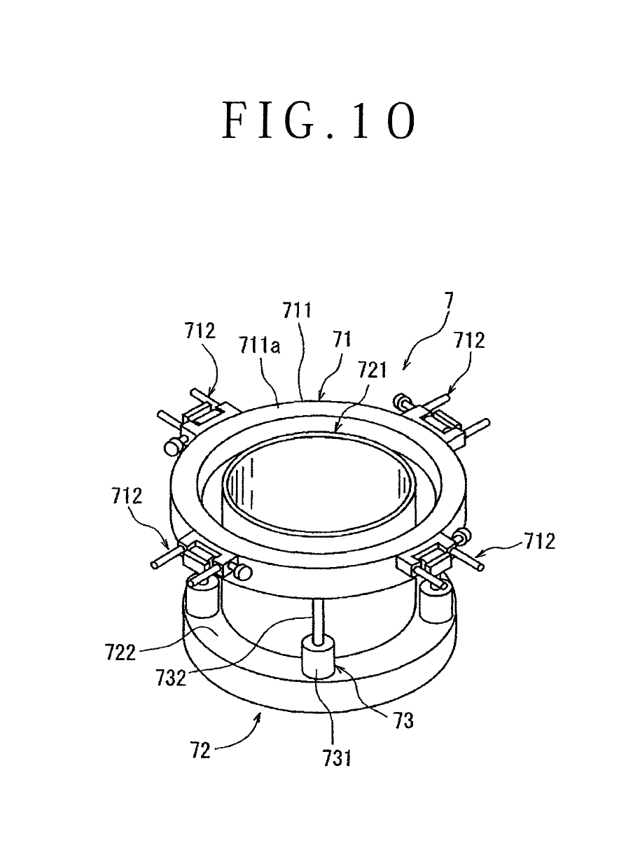

After performing the wafer supporting step and the protective tape peeling step mentioned above, a wafer dividing step is performed in such a manner that an external force is applied to the optical device wafer 2 in the condition after the reflective film cutting step (the modified layer 200 has already been formed along each street 22 at an intermediate depth in the sapphire substrate 20), thereby dividing the sapphire substrate 20 along each street 22 where the modified layer 200 is formed. This wafer dividing step is performed by using a wafer dividing apparatus 7 shown in FIG. 10. As shown in FIG. 10, the wafer dividing apparatus 7 includes frame holding means 71 for holding the annular frame 6 and tape expanding means 72 for expanding the adhesive tape 60 supported to the annular frame 6 held by the frame holding means 71. The frame holding means 71 includes an annular frame holding member 711 and a plurality of clamps 712 as fixing means provided on the outer circumference of the frame holding member 711. The upper surface of the frame holding member 711 functions as a mounting surface 711a for mounting the annular frame 6 thereon. The annular frame 6 mounted on the mounting surface 711a is fixed to the frame holding member 711 by the clamps 712. The frame holding means 71 is supported by the tape expanding means 72 so as to be vertically movable.

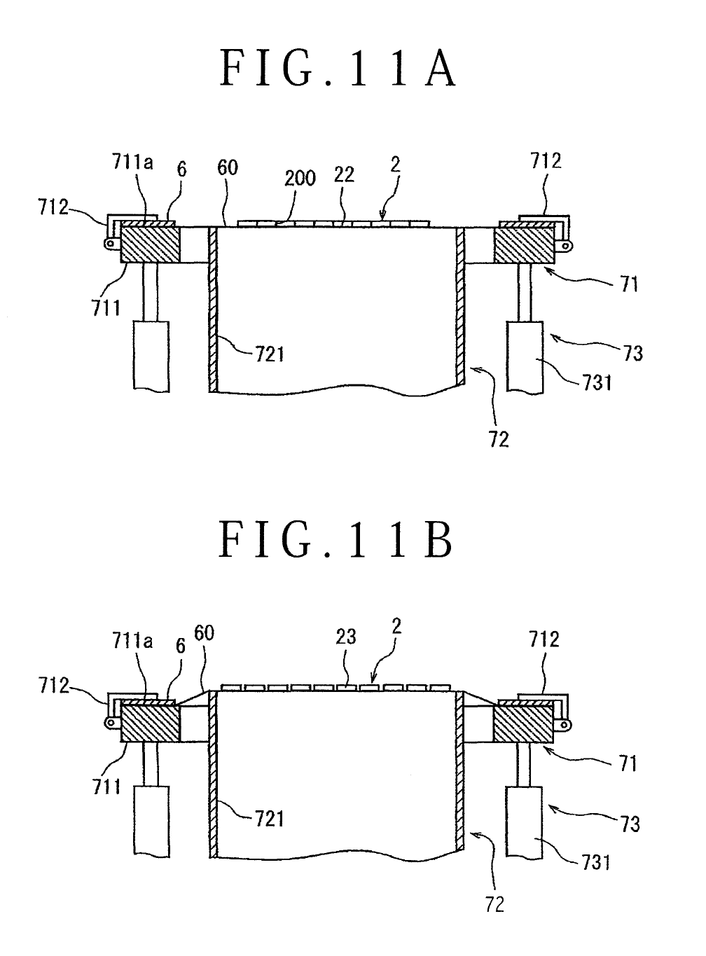

The tape expanding means 72 includes a cylindrical expanding drum 721 as a pressure member provided inside of the annular frame holding member 711. The expanding drum 721 has an outer diameter smaller than the inner diameter of the annular frame 6 and an inner diameter larger than the outer diameter of the optical device wafer 2 attached to the adhesive tape 60 supported to the annular frame 6. The expanding drum 721 has a supporting flange 722 at the lower end thereof. The tape expanding means 72 further includes supporting means 73 for vertically moving the annular frame holding member 711. The supporting means 73 is composed of a plurality of air cylinders 731 provided on the supporting flange 722. Each air cylinder 731 is provided with a piston rod 732 connected to the lower surface of the annular frame holding member 711. The supporting means 73 composed of the plural air cylinders 731 functions to vertically move the annular frame holding member 711 so as to selectively take a reference position where the mounting surface 711a is substantially equal in height to the upper end of the expanding drum 721 as shown in FIG. 11A and an expansion position where the mounting surface 711a is lower in height than the upper end of the expanding drum 721 by a predetermined amount as shown in FIG. 11B. Accordingly, the supporting means 73 composed of the plural air cylinders 731 functions as moving means for relatively moving the expanding drum 721 and the frame holding member 711 in the vertical direction.

The wafer dividing step using the wafer dividing apparatus 7 will now be described with reference to FIGS. 11A and 11B. As shown in FIG. 11A, the annular frame 6 supporting the optical device wafer 2 through the adhesive tape 60 (i.e., the back side 20b of the sapphire substrate 20 formed with the modified layer 200 extending along each street 22 on the front side 20a of the sapphire substrate 20 is attached through the reflective film 210 to the adhesive tape 60) is mounted on the mounting surface 711a of the frame holding member 711 constituting the frame holding means 71 and fixed to the frame holding member 711 by the clamps 712. At this time, the frame holding member 711 is set at the reference position shown in FIG. 11A. Thereafter, the air cylinders 731 as the supporting means 73 constituting the tape expanding means 72 are operated to lower the annular frame holding member 711 to the expansion position shown in FIG. 11B. Accordingly, the annular frame 6 fixed to the mounting surface 711a of the frame holding member 711 is also lowered, so that the adhesive tape 60 supported to the annular frame 6 comes into abutment in its annular area between the outer circumference of the optical device wafer 2 and the inner circumference of the annular frame 6 against the upper end of the cylindrical expanding drum 721 as a pressure member and is therefore expanded substantially in the radial direction of the expanding drum 721 as shown in FIG. 11B. As a result, a tensile force is radially applied to the optical device wafer 2 attached to the adhesive tape 60, and the sapphire substrate 20 constituting the optical device wafer 2 is therefore broken along each street 22 where the strength of the sapphire substrate 20 is lowered because of the presence of the modified layer 200 formed along each street 22, thereby dividing the optical device wafer 2 into the individual optical devices 23. At this time, the optical device wafer 2 can be smoothly broken along each street 22 because the reflective film 210 has already been cut by the reflective film cutting step.

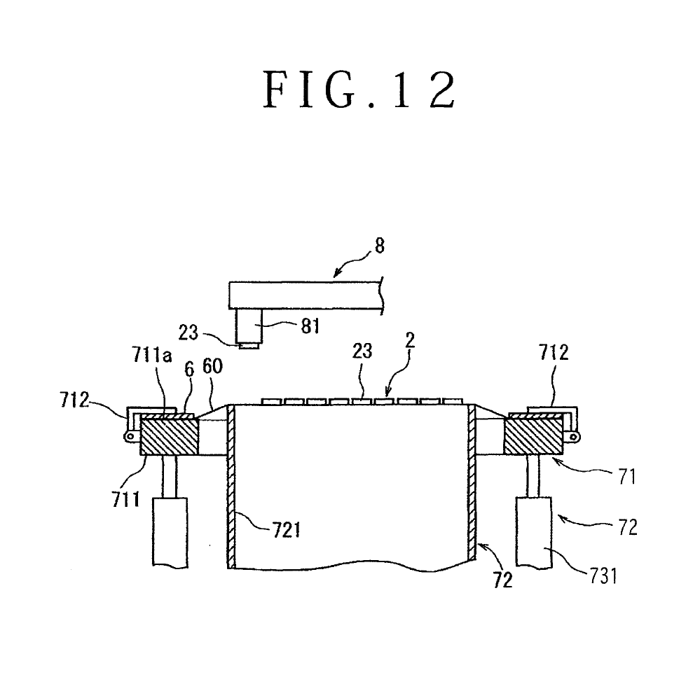

After performing the wafer dividing step mentioned above, a pickup step is performed as shown in FIG. 12 in such a manner that a pickup mechanism 8 having a pickup collet 81 is operated to pick up each optical device 23 from the adhesive tape 60. Each optical device 23 thus held by the pickup collet 81 is transported to a tray (not shown) or a die bonding stage.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. An optical device wafer processing method for dividing an optical device wafer into individual optical devices along a plurality of crossing streets formed on a front side of said optical device wafer, said optical device wafer being composed of a sapphire substrate and an optical device layer formed on a front side of said sapphire substrate, said individual optical devices being respectively formed in a plurality of regions partitioned by said streets, said optical device wafer processing method comprising:
a modified layer forming step of applying a laser beam having a transmission wavelength to said sapphire substrate along said streets from a back side of said sapphire substrate in a condition where the focal point of said laser beam is set inside said sapphire substrate, thereby forming a modified layer inside said sapphire substrate along each street;
a reflective film forming step of forming a reflective film on the back side of said sapphire substrate after performing said modified layer forming step;
a reflective film cutting step of applying a laser beam having an absorption wavelength to said reflective film along said streets from the back side of said sapphire substrate after performing said reflective film forming step, thereby cutting said reflective film along each street; and
a wafer dividing step of applying an external force to said optical device wafer after performing said reflective film cutting step, thereby breaking said optical device wafer along each street where said modified layer is formed, so that said optical device wafer is divided into said individual optical devices.

2. The optical device wafer processing method according to claim 1, wherein said reflective film includes a metal film having a thickness of 0.5 to 2 μm.

3. The optical device wafer processing method according to claim 1, wherein said reflective film includes an oxide film having a thickness of 0.5 to 2 μm.
